(19) United States
(12) Patent Application Publication
(10) Pub. No.: US 2015/0129834 A1
(43) Pub. Date: May 14, 2015

(54) SEMICONDUCTOR LIGHT EMITTING DEVICE

(71) Applicant: SAMSUNG ELECTRONICS CO., LTD., Suwon-si (KR)

(72) Inventors: Nam Goo CHA, Ansan-si (KR); Dong Hoon LEE, Seoul (KR); Min Wook CHOI, Gimpo-si (KR); Kyung Wook HWANG, Hwaseong-si (KR)

(21) Appl. No.: 14/472,089

(22) Filed: Aug. 28, 2014

(30) Foreign Application Priority Data
Nov. 12, 2013 (KR) 10-2013-0136763

(51) Int. Cl. H01L 33/24; H01L 33/42; H01L 33/06

(52) U.S. Cl. CPC H01L 33/24; H01L 33/06; H01L 33/42
USPC 257/13

(57) ABSTRACT

There is provided a semiconductor light emitting device including a first conductivity-type semiconductor base layer, a plurality of light emitting nanostructures disposed on the first conductivity-type semiconductor base layer to be spaced apart from one another, each light emitting nanostructure including a first conductivity-type semiconductor core, an active layer and a second conductivity-type semiconductor layer, and a filling layer including a refractive portion disposed between the light emitting nanostructures and a cover portion filled between the light emitting nanostructures and enclosing the refractive portion.

### CROSS-REFERENCE TO RELATED APPLICATION

This application claims the benefit of priority to Korean Patent Application No. 10-2013-0136763 filed on Nov. 12, 2013, with the Korean Intellectual Property Office, the entire contents of which are hereby incorporated by reference.

### TECHNICAL FIELD

The present disclosure relates to nano-structured light-emitting devices and methods for manufacturing the same.

### BACKGROUND

A light emitting diode (LED) is known as a next generation light source having various advantages such as long lifespan, low power consumption, rapid response speed, environmentally friendliness, and the like, as compared to conventional light sources. LEDs have emerged as light sources for various products such as lighting devices, backlights of display devices, and the like. In particular, LEDs formed of group III nitride semiconductors such as GaN, AlGaN, InGaN, InAlGaN, and the like, have played a significant role as semiconductor light emitting devices outputting blue light or ultraviolet light.

In recent years, the applications of LEDs have been extended to high current/high output light sources. As LEDs are demanded in the fields of high current/high output light sources, research into improvement of light emitting characteristics has been continuously conducted. In particular, in order to improve light emitting efficiency through improvement of crystalline properties and an increase in light emitting areas, a semiconductor light emitting device having a light emitting nanostructure, and a method of manufacturing the same, have been proposed.

In general, a nano LED including light emitting nanostructures is vulnerable to external impact due to a high aspect ratio of the light emitting nanostructures, thus making it necessary to fill a material between the light emitting nanostructures. However, in the case of using an oxide film formation method using a wet process such as a spin on glass (SOG) process, it is difficult to implement uniform filling.

Accordingly, a need exists for an LED formed by filling a material between adjacent light emitting nanostructures through a dry process.

### SUMMARY

An aspect of the present disclosure may provide a semiconductor light emitting device having improved light extraction efficiency and reduced stress by disposing a filling layer including a refractive portion between light emitting nanostructures.

An aspect of the present disclosure relates to a semiconductor light emitting device including a first conductivity-type semiconductor base layer; a plurality of light emitting nanostructures disposed spaced apart from one another on the first conductivity-type semiconductor base layer, each light emitting nanostructure including a first conductivity-type semiconductor core, an active layer and a second conductivity-type semiconductor layer; and a filling layer including a refractive portion disposed between the light emitting nanostructures and a cover portion filled between the light emitting nanostructures and enclosing the refractive portion.

The refractive portion may be a void formed inside the cover portion.

The refractive portion may include a material having a refractive index different from a refractive index of the cover portion and the light emitting nanostructures.

The cover portion may be disposed on the first conductivity-type semiconductor base layer between the light emitting nanostructures while covering at least a part of top and side surfaces of the light emitting nanostructures.

At least portions of the cover portion may be continuously disposed above the light emitting nanostructures.

A top portion of the refractive portion may be exposed through a top of the filling layer.

Upper portions of the light emitting nanostructures may protrude above a top of the filling layer.

The refractive portion may include at least one refractive portion disposed between each pair of adjacent light emitting nanostructures.

The light emitting nanostructures may have a hexagonal cross-section at a surface parallel to a top surface of the first conductivity-type semiconductor base layer, and six of the light emitting nanostructures may be arranged to surround a single light emitting nanostructure.

The refractive portion may include six or more refractive portions disposed around the single light emitting nanostructure.

The light emitting nanostructure may include a first region having a hexagonal pyramid shape disposed in an upper portion thereof; and a second region having a hexagonal column shape disposed below the first region.

The light emitting nanostructure may further include a transparent electrode layer disposed on the second conductivity-type semiconductor layer.

The transparent electrode layer may be continuously disposed on adjacent light emitting nanostructures.

The semiconductor light emitting device may further include first to third regions, wherein the plurality of light emitting nanostructures may be disposed to have different distances in the first to third regions, and the refractive portion may have different sizes in proportion to the distances.

Another aspect of the present disclosure relates to a semiconductor light emitting device including a first conductivity-type semiconductor base layer; a plurality of light emitting nanostructures disposed spaced apart from one another on the first conductivity-type semiconductor base layer, each light emitting nanostructure including a first conductivity-type semiconductor core, an active layer and a second conductivity-type semiconductor layer; and a filling layer filled between the light emitting nanostructures and having a void formed therein.

Another aspect of the present disclosure relates to a semiconductor light emitting device including a first conductivity-type semiconductor base layer, a plurality of light emitting nanostructures disposed spaced apart from one another on the first conductivity-type semiconductor base layer, each light emitting nanostructure including a first conductivity-type semiconductor core, an active layer and a second conductivity-type semiconductor layer, and a filling layer covering the plurality of light emitting nanostructures and filling the space between the light emitting nanostructures, the filling layer having voids between the light emitting nanostructures, wherein the filling layer has a higher top surface in the area below which the plurality of light emitting nanostructures are located than that of the area below which the voids are located.

The lighting device may include wherein the light emitting nanostructures have a hexagonal cross-section at a surface parallel to a top surface of the first conductivity-type semiconductor base layer, and six of the light emitting nanostructures are arranged to surround a single light emitting nanostructure.

The lighting device may also include wherein the light emitting nanostructure includes a first region having a hexagonal pyramid shape disposed in an upper portion thereof, and a second region having a hexagonal column shape disposed below the first region.

The lighting device may further include wherein the light emitting nanostructure further includes a transparent electrode layer disposed on the second conductivity-type semiconductor layer.

The lighting device may also include wherein the transparent electrode layer is continuously disposed on adjacent light emitting nanostructures.

### BRIEF DESCRIPTION OF DRAWINGS

The foregoing and other features of the present disclosure will be apparent from more particular description of embodiments of the inventive concept, as illustrated in the accompanying drawings in which like reference characters may refer to the same or similar elements throughout the different views. The drawings are not necessarily to scale, emphasis instead being placed upon illustrating the principles of the embodiments of the inventive concept. In the drawings, the thickness of layers and regions may be exaggerated for clarity.

The above and other aspects, features and other advantages of the present disclosure will be more clearly understood from the following detailed description taken in conjunction with the accompanying drawings, in which:

FIG. 1 is a front elevation cross-sectional view illustrating a semiconductor light emitting device according to an exemplary embodiment of the present disclosure;

FIGS. 2A and 2B are plan views illustrating a structure of a semiconductor light emitting device according to an exemplary embodiment of the present disclosure;

FIGS. 3A through 3F are front elevation cross-sectional views illustrating a method of manufacturing a semiconductor light emitting device according to an exemplary embodiment of the present disclosure;

FIG. 4 is a front elevation cross-sectional view illustrating a semiconductor light emitting device according to an exemplary embodiment of the present disclosure;

FIG. 5 is a front elevation cross-sectional view illustrating a semiconductor light emitting device according to an exemplary embodiment of the present disclosure;

FIGS. 6A and 6B are perspective views illustrating a first conductivity-type semiconductor core applicable to a semiconductor light emitting device according to an exemplary embodiment of the present disclosure;

FIGS. 7A and 7B are electron micrographs of a semiconductor light emitting device according to an exemplary embodiment of the present disclosure;

FIG. 8 is an electron micrograph of a semiconductor light emitting device according to an exemplary embodiment of the present disclosure;

FIG. 9 is a front elevation cross-sectional view illustrating a semiconductor light emitting device according to an exemplary embodiment of the present disclosure;

FIGS. 10 and 11 are front elevation cross-sectional views illustrating examples of a semiconductor light emitting device according to an exemplary embodiment of the present disclosure applied to a package;

FIGS. 12 and 13 are front elevation cross-sectional views illustrating examples of a semiconductor light emitting device according to an exemplary embodiment of the present disclosure applied to a backlight unit;

FIG. 14 is an exploded perspective view illustrating an example of a semiconductor light emitting device according to an exemplary embodiment of the present disclosure applied to a lighting device; and

FIG. 15 is a front elevation cross-sectional view illustrating an example of a semiconductor light emitting device according to an exemplary embodiment of the present disclosure applied to a headlamp.

### DETAILED DESCRIPTION

Exemplary embodiments of the present disclosure will now be described in detail with reference to the accompanying drawings.

The disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

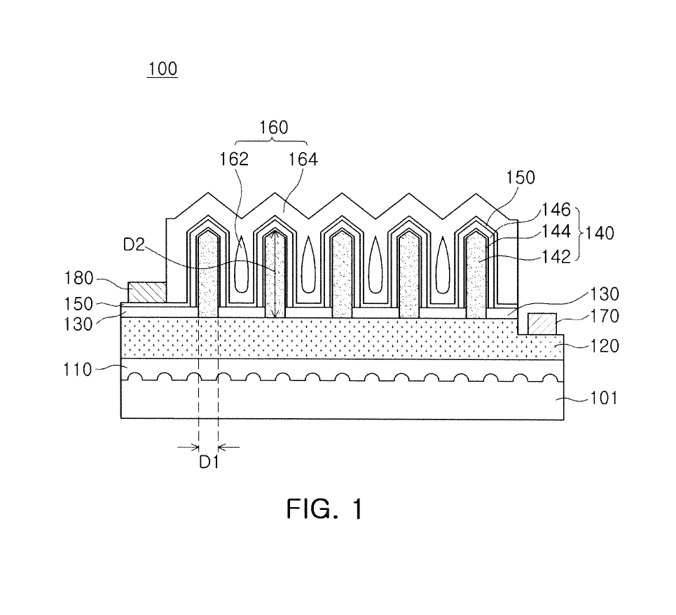

FIG. 1 is a schematic cross-sectional view illustrating a semiconductor light emitting device according to an exemplary embodiment of the present disclosure.

With reference to FIG. 1, a semiconductor light emitting device 100 may include a substrate 101, a first conductivity-type semiconductor base layer 120 formed on the substrate 101, an insulating layer 130, a light emitting nanostructure 140, a transparent electrode layer 150 and a filling layer 160. The light emitting nanostructure 140 may include a first conductivity-type semiconductor core 142 grown from the first conductivity-type semiconductor base layer 120, an active layer 144 and a second conductivity-type semiconductor layer 146. The semiconductor light emitting device 100 may further include first and second electrodes 170 and 180 electrically connected to the first conductivity-type semiconductor base layer 120 and the second conductivity-type semiconductor layer 146, respectively.

Throughout the specification, unless otherwise defined, the terms “top portion” or “upper portion,” “top surface,” “bottom portion” or “lower portion,” “bottom surface,” “side surface,” and the like, are based on the directionality of the drawings, which may be changed according to a direction in which a semiconductor light emitting device is actually mounted.

The substrate 101 may be a semiconductor growth substrate, and may be made of an insulating, conductive or semiconductor material, such as sapphire, SiC, MgAl₂O₄, MgO, LiAlO₂, LiGaO₂, GaN or the like. In a case of the substrate 101 made of sapphire, a crystal having Hexa-Rhombo R3C symmetry, the sapphire substrate has a lattice constant of 13.001 Å along a C-axis and a lattice constant of 4.758 Å along an A-axis and includes a C (0001) plane, an A (11-20) plane, an R (1-102) plane, and the like. The C plane is mainly used as a substrate for nitride semiconductor growth because it facilitates growth of a nitride film and is stable at high temperatures. Meanwhile, in a case in which the substrate 101 is made of Si, the Si substrate may be easily formed to have a large diameter and may be relatively cheap, whereby manufacturing yields may be improved.

Uneven portions may be formed on a surface of the substrate 101, thereby improving light extraction efficiency. The shape of the uneven portion is not limited to that illustrated in the drawing. According to exemplary embodiments, a buffer layer 110 may be further formed on the substrate 101 in order to improve crystalline properties of the first conductivity-type semiconductor base layer 120. The buffer layer 110 may, for example, be formed of AlₓGa₁₋ₓN grown at low temperatures without doping.

The first conductivity-type semiconductor base layer 120 may be disposed on the substrate 101. The first conductivity-type semiconductor base layer 120 may be formed of group III-V compound semiconductors, such as GaN and the like. For example, the first conductivity-type semiconductor base layer 120 may be an n-GaN layer doped with n-type impurities.

In the present embodiment, the first conductivity-type semiconductor base layer 120 may provide a crystal plane used for growing the first conductivity-type semiconductor core 142 of the light emitting nanostructure 140, and may be connected in common with one end of individual light emitting nanostructures 140 to serve as a contact electrode.

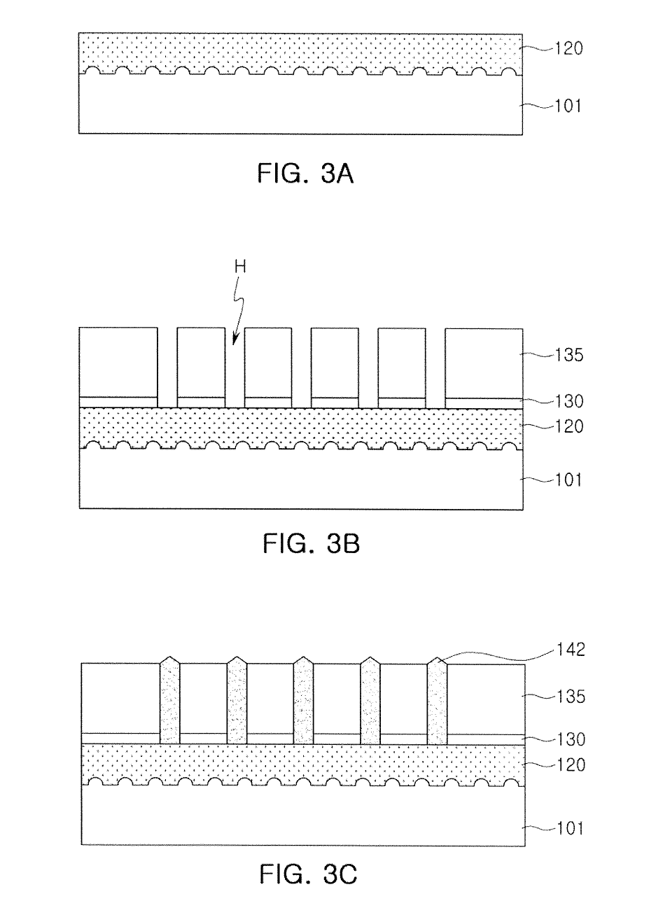

The insulating layer 130 may be disposed on the first conductivity-type semiconductor base layer 120. The insulating layer 130 may be formed of a silicon oxide or a silicon nitride. For example, the insulating layer 130 may be formed of at least one of SiOₓ, SiOₓN_{y}, SiₓN_{y}, Al₂O₃, TiN, AlN, ZrO, TiAlN, and TiSiN. The insulating layer 130 may include a plurality of openings (see FIG. 3B) exposing portions of the first conductivity-type semiconductor base layer 120. The diameters, lengths, positions and growth conditions of the light emitting nanostructures 140 may be determined according to sizes of the openings. The plurality of openings may have various shapes such as a circular shape, a quadrangular shape, a hexagonal shape, or the like.

The plurality of light emitting nanostructures 140 may be formed in positions corresponding to the plurality of openings. The light emitting nanostructure 140 may have a core-shell structure including the first conductivity-type semiconductor core 142 grown on a portion of the first conductivity-type semiconductor base layer 120 exposed through the opening, and the active layer 144 and the second conductivity-type semiconductor layer 146 sequentially grown on a surface of the first conductivity-type semiconductor core 142.

The first conductivity-type semiconductor core 142 and the second conductivity-type semiconductor layer 146 may be formed of semiconductor materials doped with n-type and p-type impurities, respectively, but are not limited thereto. On the contrary, the first conductivity-type semiconductor core 142 and the second conductivity-type semiconductor layer 146 may be formed of semiconductor materials doped with p-type and n-type impurities, respectively. The first conductivity-type semiconductor core 142 and the second conductivity-type semiconductor layer 146 may be formed of a nitride semiconductor, for example, a material having a composition of AlₓIn_{y}Ga_{1-x-y}N, where 0≦x≦1, 0≦y≦1, and 0≦x+y≦1, each of which may be formed as a single layer or as a plurality of layers having different characteristics in terms of doping concentration, composition, and the like. However, the first conductivity-type semiconductor core 142 and the second conductivity-type semiconductor layer 146 may also be formed of an AlInGaP or AlInGaAs semiconductor, besides the nitride semiconductor. In the present embodiment, the first conductivity-type semiconductor core 142 may be formed of an n-GaN doped with Si or C and the second conductivity-type semiconductor layer 146 may be formed of a p-GaN doped with Mg or Zn.

The active layer 144 may be disposed on the first conductivity-type semiconductor core 142. The active layer 144 may emit light having a predetermined level of energy through a recombination of electrons and holes. The active layer 144 may be a layer formed of a single material such as InGaN or the like. Alternatively, the active layer 144 may have a single quantum well (SQW) structure or a multi-quantum well (MQW) structure in which quantum barrier layers and quantum well layers are alternately stacked. For example, in the case of the nitride semiconductor, a GaN/InGaN structure may be used. In a case in which the active layer 144 includes InGaN, an increase in the content of In may alleviate crystalline defects resulting from a lattice mismatch and improve internal quantum efficiency of the semiconductor light emitting device 100. In addition, wavelengths of light emitted from the active layer 144 may be adjusted according to the content of In within the active layer 144.

The number of the light emitting nanostructures 140 included in the semiconductor light emitting device 100 is not limited to that illustrated in the drawing. For example, the semiconductor light emitting device 100 may include tens to millions of light emitting nanostructures 140. In the present embodiment, the light emitting nanostructure 140 may be formed of a lower hexagonal column region and an upper hexagonal pyramid region. The light emitting nanostructure 140 according to the is present embodiment may have a first width D1 of the hexagonal column region and a second length D2 from a bottom surface of the hexagonal column region to the top of the hexagonal pyramid region, the second length D2 being greater than the first width D1. An aspect ratio of the light emitting nanostructure 140 may range from 1:5 to 1:15. In a case in which the light emitting nanostructure 140 has a relatively high aspect ratio, the light emitting nanostructure 140 may have an inclined side surface with the width narrowing as the light emitting nanostructure 140 become closer to the substrate 101. According to exemplary embodiments, the light emitting nanostructure 140 may have a pyramid shape or a column shape. Since the light emitting nanostructure 140 has a three-dimensional shape, a light emitting area may be relatively large and luminous efficiency may be improved.

The transparent electrode layer 150 may be electrically connected to the second conductivity-type semiconductor layer 146. The transparent electrode layer 150 may cover top and side surfaces of the light emitting nanostructure 140 and may be continuously formed between the adjacent light emitting nanostructures 140. The transparent electrode layer 150 may be formed of, for example, ITO (indium tin oxide), AZO (aluminium zinc oxide), IZO (indium zinc oxide), ZnO, GZO (ZnO:Ga), In₂O₃, SnO₂, CdO, CdSnO₄, or Ga₂O₃.

The filling layer 160 may include a refractive portion 162 and a cover portion 164, and may be disposed above the light emitting nanostructure 140 and the transparent electrode layer 150.

The refractive portion 162 may be disposed between adjacent light emitting nanostructures 140, and may be formed of a light transmissive material having refractive indices different from those of the light emitting nanostructure 140 and the cover portion 164. For example, the refractive portion 162 may be formed of air. In this case, the refractive portion 162 may be a void formed within the filling layer 160. For example, in a case in which the light emitting nanostructure 140 is formed of GaN having a refractive index of approximately 2.3 and the cover portion 164 is formed of SiO₂ having a refractive index of approximately 1.5, the refractive portion 162 may be formed of air having a refractive index of 1. According to exemplary embodiments, the refractive portion 162 may be formed of a material having a refractive index higher than 2.3 or lower than 1.5.

The refractive portion 162 may have a waterdrop shape having a lower width greater than an upper width. The shape of the refractive portion 162 is not limited thereto, and may be changed within a range in which at least bottom and side surfaces of the refractive portion 162 are enclosed by the cover portion 164 between the adjacent light emitting nanostructures 140.

The cover portion 164 may be extended to cover the light emitting nanostructures 140 and the transparent electrode layer 150 formed on the light emitting nanostructures 140, and may be filled between the adjacent light emitting nanostructures 140 while enclosing the refractive portion 162.

The cover portion 164 may be formed of a light transmissive insulating material. For example, the cover portion 164 may include SiO₂, SiNₓ, Al₂O₃, HfO, TiO₂ or ZrO. According to exemplary embodiments, the cover portion 164 may include a conductive material. In this case, the cover portion 164 may be disposed to be connected to the second electrode 180.

Light generated in the active layer 144 may be emitted from the light emitting nanostructures 140 to the top of the semiconductor light emitting device 100 through the filling layer 160. In this case, since the filling layer 160 includes the refractive portion 162, a path of light may be varied, whereby light extraction efficiency may be improved. According to a result of simulation, in a case in which the refractive portion 162 is formed of air, light extraction efficiency increased by approximately 2% as compared with a case in which the refractive portion 162 is not formed.

In addition, the refractive portion 162 may serve as a damper with respect to stress or deformation due to thermal expansion, physical reaction, and the like, occurring during or after the manufacturing of the semiconductor light emitting device 100, thereby alleviating the stress and preventing the deformation.

According to an exemplary embodiment, a passivation layer may be further disposed to cover the filling layer 160. The passivation layer may be disposed to expose top surfaces of the first and second electrodes 170 and 180.

The first and second electrodes 170 and 180 may be disposed on the first conductivity-type semiconductor base layer 120 and the transparent electrode layer 150 at one side of the semiconductor light emitting device 100 such that they are electrically connected to the first conductivity-type semiconductor base layer 120 and the second conductivity-type semiconductor layer 146, respectively. The first and second electrodes 170 and 180 may have a single layer structure or a multilayer structure formed of a conductive material. For example, the first and second electrodes 170 and 180 may include at least one of Au, Ag, Cu, Zn, Al, In, Ti, Si, Ge, Sn, Mg, Ta, Cr, W, Ru, Rh, Ir, Ni, Pd, Pt and alloys thereof.

According to exemplary embodiments, in a case in which the substrate 101 is formed of a conductive material, the first electrode 170 may be disposed on the bottom of the substrate 101, or may be omitted.

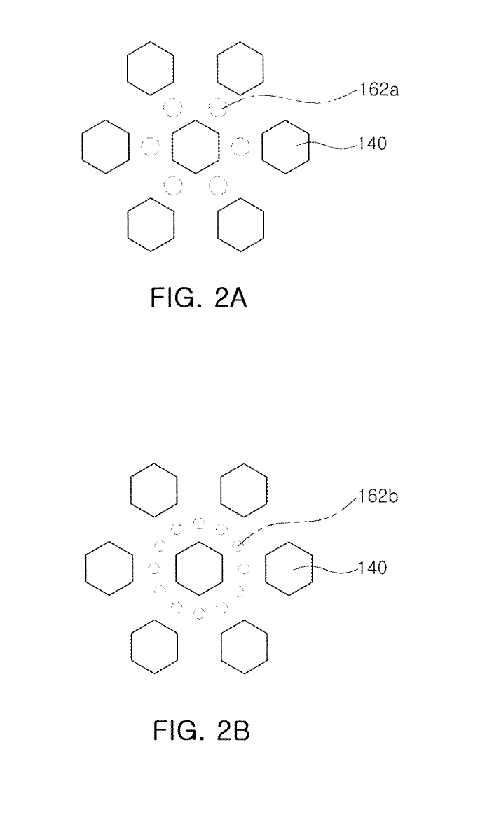

FIGS. 2A and 2B illustrate the arrangement of a single light emitting nanostructure 140 disposed at the center and adjacent light emitting nanostructures 140 along with refractive portions 162a and 162b, constituting the semiconductor light emitting device of FIG. 1, in a plan view.

With reference to FIGS. 2A and 2B, the light emitting nanostructures 140 may have a hexagonal cross-section cut at a surface parallel to the top surface of the substrate 101 (see FIG. 1) and may be arranged in a hexagonal pattern. Therefore, a single light emitting nanostructure 140 may be surrounded by six light emitting nanostructures 140.

In FIG. 2A, a single refractive portions 162a may be disposed between each pair of adjacent light emitting nanostructures 140. In FIG. 2B, one or more refractive portions 162b may be disposed between each pair of adjacent light emitting nanostructures 140. For example, FIG. 2B illustrates that twelve refractive portions 162b are disposed around the single light emitting nanostructure 140. However, the number of refractive portions 162b disposed around the single light emitting nanostructure 140 is not limited to that illustrated in the drawing and may be varied. As the number of refractive portions 162a or 162b increases, the size of each refractive portion 162a or 162b may be relatively reduced.

By simulating cases in which the heights of the refractive portions 162a and 162b are the same and the size and the number thereof are different, the light emitting nanostructures 140 were tested to evaluate thermal stress. The simulation was performed with respect to cases in which the refractive portions 162a and 162b are formed of voids. As a result of the simulation, when six refractive portions 162a having a width of 700 nm were disposed around a single light emitting nanostructure 140 as illustrated in FIG. 2A, thermal stress was reduced by 17.2% as compared with a case in which there was no refractive portion. In addition, when twelve refractive portions 162b having a width of 400 nm were disposed around a single light emitting nanostructure 140 as illustrated in FIG. 2B, thermal stress was reduced by 11.0% as compared with a case in which there was no refractive portion.

Therefore, the effect of reducing thermal stress may be increased as a total volume of the refractive portions 162a and 162b increases; however, the cover portion 164 becomes relatively thin. Accordingly, the size and the number of refractive portions may be appropriately selected according to the characteristics of semiconductor light emitting devices to be adopted.

FIGS. 3A through 3F illustrate a method of manufacturing the semiconductor light emitting device 100 of FIG. 1.

With reference to FIG. 3A, uneven portions may be formed on a top surface of the substrate 101, and a first conductivity-type semiconductor may be grown on the substrate 101 to thereby form the first conductivity-type semiconductor base layer 120.

The first conductivity-type semiconductor base layer 120 may be provided as a crystal plane on which the light emitting structures 140 (see FIG. 1) are grown, and may be provided as a structure electrically connecting one ends of the light emitting nanostructures 140 to one another. Therefore, the first conductivity-type semiconductor base layer 120 may be formed of a semiconductor single crystal having electrical conductivity, and in this case, the substrate 101 may be a crystal growth substrate.

With reference to FIG. 3B, the insulating layer 130 and a mask layer 135 including a plurality of openings H may be formed on the first conductivity-type semiconductor base layer 120 to thereby expose portions of the first conductivity-type semiconductor base layer 120 through the plurality of openings H.

First, an insulting material forming the insulating layer 130 and a material forming the mask layer 135 are consecutively deposited and patterned with a mask pattern (not shown), thereby forming the insulating layer 130 and the mask layer 135. The insulating layer 130 and the mask layer 135 may be formed of materials having different etch rates under predetermined etching conditions, and thus, the etching process of forming the plurality of openings H may be controlled. For example, the insulating layer 130 may be formed of SiN, and the mask layer 135 may be formed of SiO₂.

A total thickness of the insulating layer 130 and the mask layer 135 may be determined in consideration of a height of the light emitting nanostructure 140 (see FIG. 1) to be formed. In addition, a size of the opening H may be determined in consideration of a size of the light emitting nanostructure 140 to be formed. For example, a width of the opening H may be 500 nm or less. An aspect ratio of the opening H may be 5:1 or higher, for example, 10:1 or higher.

With reference to FIG. 3C, a first conductivity-type semiconductor may be grown on the exposed portions of the first conductivity-type semiconductor base layer 120 while filling the plurality of openings H, thereby forming the plurality of first conductivity-type semiconductor cores 142.

The first conductivity-type semiconductor cores 142 may be formed of, for example, an n-type nitride semiconductor, and may be formed of the same material as that of the first conductivity-type semiconductor base layer 120. The first conductivity-type semiconductor cores 142 may be fowled using metal organic chemical vapor deposition (MOCVD) or molecular beam epitaxy (MBE).

With reference to FIG. 3D, the mask layer 135 may be removed to expose side surfaces of the plurality of first conductivity-type semiconductor cores 142, and the active layer 144, the second conductivity-type semiconductor layer 146 and the transparent electrode layer 150 may be formed.

First, the mask layer 135 may be selectively removed with respect to the insulating layer 130 and the first conductivity-type semiconductor cores 142, thereby allowing the insulting layer 130 to remain. The removal process may be, for example, performed by wet etching. The insulting layer 130 may serve to prevent the active layer 144 and the second conductivity-type semiconductor layer 146 from contacting the first conductivity-type semiconductor base layer 120 in post processing.

According to exemplary embodiments, after the removal of the mask layer 135, a heat treatment may be additionally implemented to change crystal planes of the first conductivity-type semiconductor cores 142 into stable planes advantageous to crystal growth, such as semi-polar or non-polar crystal planes.

Next, the active layer 144 and the second conductivity-type semiconductor layer 146 may be sequentially grown on the surfaces of the first conductivity-type semiconductor cores 142, thereby forming the light emitting nanostructures 140 having a core-shell structure.

Then, the transparent electrode layer 150 may be formed on the light emitting nanostructures 140. The transparent electrode layer 150 may be continuously formed to cover a top surface of the insulating layer 130 between the adjacent light emitting nanostructures 140, such that it may be formed as a single layer on the plurality of light emitting nanostructures 140.

With reference to FIGS. 3E and 3F, the filling layer 160 may be formed on the transparent electrode layer 150.

First, a cover material layer 164P forming the cover portion 164 may be formed above the light emitting nanostructures 140 and the transparent electrode layer 150 as illustrated in FIG. 3E. Since the light emitting nanostructures 140 have a high aspect ratio, when the cover material layer 164P is deposited between the adjacent light emitting nanostructures 140, overhangs and non-filling regions v below the overhangs may be formed. Here, the overhangs refer to portions of the cover material layer 164P protruding from upper portions of the light emitting nanostructures 140 as compared to lower portions thereof. As the overhangs are connected to one another, the non-filling regions v in which the deposition material is not filled may be formed below the connected overhangs.

As the cover material layer 164P becomes thick, the cover material layer 164P may be connected with each other above the upper portions of the light emitting nanostructures 140. Therefore, the cover portion 164 having the refractive portion 162 formed therein may be formed as illustrated in FIG. 3F, and thus, the filling layer 160 including the refractive portion 162 and the cover portion 164 may be formed. In the present embodiment, the refractive portion 162 may be a void including air.

According to exemplary embodiments, the cover portion 164 may be formed of a plurality of layers. The plurality of layers may be formed of different materials, or even in the case in which the plurality of layers is formed of the same material, they may be formed by different deposition processes. For example, in a case in which the cover portion 164 is formed of a silicon oxide, the cover portion 164 may be formed using a source gas including SiH₃ gas up to a predetermined thickness and then using tetraethoxysilane (TEOS). By adjusting the material of the cover portion 164 and processing conditions such as temperature and an amount of the source gas, the size and position of the refractive portion 162 formed inside the cover portion 164 may be adjusted.

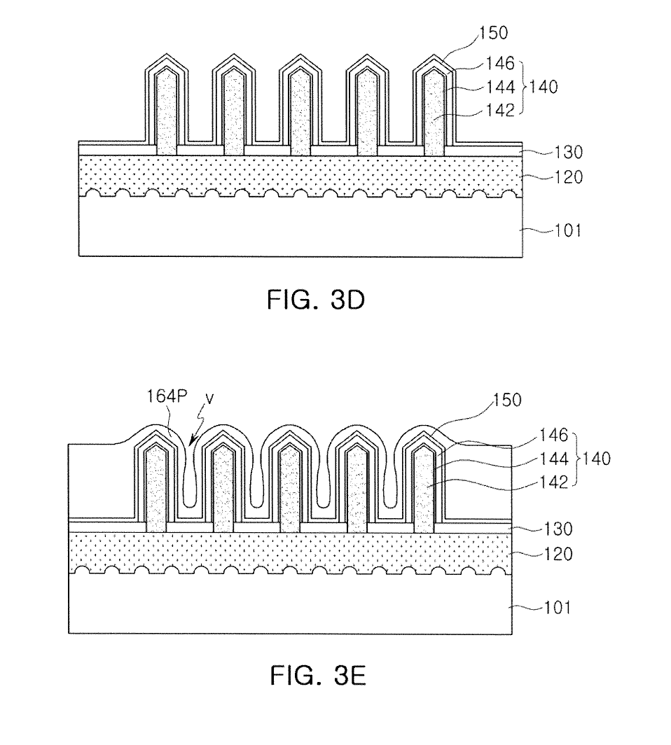

With reference to FIG. 4, a semiconductor light emitting device 100a may include the substrate 101, the first conductivity-type semiconductor base layer 120 formed on the substrate 101, the insulating layer 130, the light emitting nanostructure 140, the transparent electrode layer 150 and a filling layer 160c. The light emitting nanostructure 140 may include the first conductivity-type semiconductor core 142 grown from the first conductivity-type semiconductor base layer 120, the active layer 144 and the second conductivity-type semiconductor layer 146. The semiconductor light emitting device 100a may further include the first and second electrodes 170 and 180.

The filling layer 160c may include a refractive portion 162c and a cover portion 164c, and may be disposed on the light emitting nanostructure 140 and the transparent electrode layer 150.

In particular, unlike the exemplary embodiment of FIG. 1, a top portion of the refractive portion 162c in the present embodiment may be disposed to be exposed through the cover portion 164c. Therefore, the cover portion 164c may be disposed to enclose bottom and side surfaces of the refractive portion 162c. The refractive portion 162c may be spaced apart from the transparent electrode layer 150 by a third length D3 between the light emitting nanostructures 140. The third length D3 may vary according to a gap between the light emitting nanostructure 140, a thickness of the cover portion 164c and formation conditions of the cover portion 164c. The top of the refractive portion 162c may be lower than the top of the cover portion 164c by a fourth length D4, and the fourth length D4 may vary according to exemplary embodiments.

The refractive portion 162c may be formed of, for example, a water glass layer, a spin-on-glass (SOG) layer, a spin-on-dielectric (SOD) layer, or the like. In the above process described with reference to FIG. 3E, the refractive portion 162c may be formed by filling a non-filling region v with a material having a refractive index different from that of the cover portion 164c and the light emitting nanostructure 140, such as a water glass layer, an SOG layer, an SOD layer, or the like, in a state in which a top portion of the non-filling region v is open. In addition, according to exemplary embodiments, in a state in which the filling layer 160 is formed as illustrated in FIG. 3F, an etch back process may be pertained to remove an upper portion of the cover portion 164 at a predetermined thickness so that the refractive portion 162 is exposed, whereby the filling layer 160c according to the present embodiment may be formed.

The refractive portion 162c according to the present embodiment is formed to have the top portion exposed through the surface of the filling layer 160c, and thus, the refractive portion 162c may be easily filled with the material having a refractive index different from that of the cover portion 164c and the light emitting nanostructure 140.

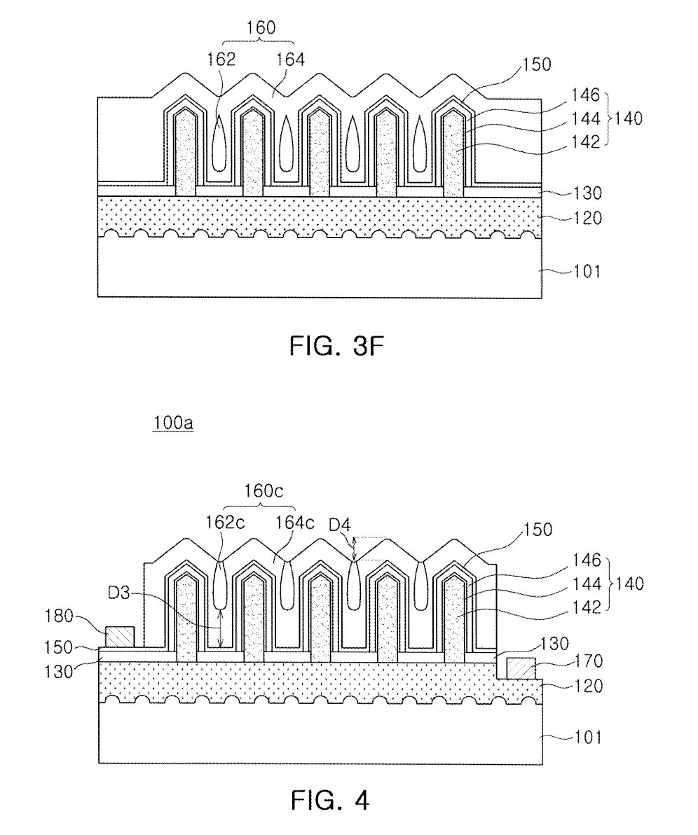

With reference to FIG. 5, a semiconductor light emitting device 100b may include the substrate 101, the first conductivity-type semiconductor base layer 120 formed on the substrate 101, the insulating layer 130, the light emitting nanostructure 140, the transparent electrode layer 150 and a filling layer 160d. The light emitting nanostructure 140 may include the first conductivity-type semiconductor core 142 grown from the first conductivity-type semiconductor base layer 120, the active layer 144 and the second conductivity-type semiconductor layer 146. The semiconductor light emitting device 100a may further include the first and second electrodes 170 and 180.

The filling layer 160d may include a refractive portion 162d and a cover portion 164d, and may be disposed above the light emitting nanostructure 140 and the transparent electrode layer 150.

In particular, unlike the embodiment of FIG. 1, the cover portion 164d according to the present embodiment may only be disposed around the side portions of the light emitting nanostructures 140 such that the upper portions of the light emitting nanostructures 140 are exposed. The top of the cover portion 164d may be lower than the top of the transparent electrode layer 150 formed on the top surface of the light emitting nanostructure 140 by a fifth length D5, and the fifth length D5 may vary according to exemplary embodiments.

For example, in a case in which the filling layer 160 is formed as illustrated in FIG. 3F, an etch back process may be performed to remove an upper portion of the cover portion 164 at a predetermined thickness so that the upper portions of the light emitting structures 140 are exposed, whereby the filling layer 160d according to the present embodiment may be formed.

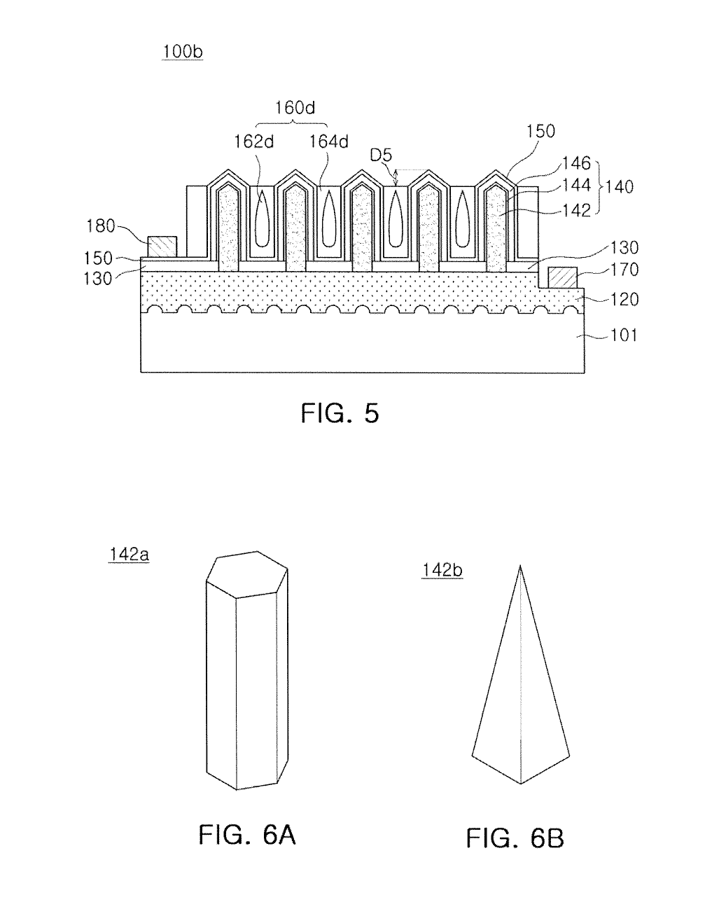

With reference to FIG. 6A, a first conductivity-type semiconductor core 142a may have a hexagonal column shape. According to exemplary embodiments, the first conductivity-type semiconductor core 142a may have a polygonal column shape such as a cylindrical shape or a rectangular column shape.

With reference to FIG. 6B, a first conductivity-type semiconductor core 142b may have a pyramidal shape. According to exemplary embodiments, the first conductivity-type semiconductor core 142b may have various shapes of which a cross section becomes smaller in a direction toward the top.

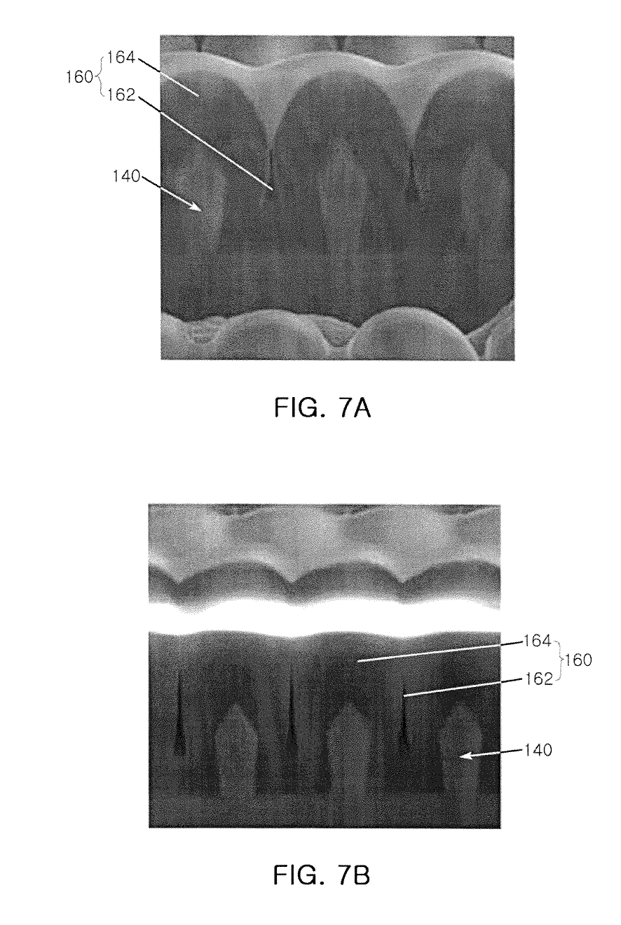

FIGS. 7A and 7B illustrate cross sections of the light emitting nanostructures 140 and the filling layer 160 analyzed by scanning electron microscopy (SEM).

FIG. 7A illustrates the filling layer 160 formed on the light emitting nanostructures 140 by depositing an insulating material at a first thickness through plasma enhanced chemical vapor deposition (PECVD). FIG. 7B illustrates the filling layer 160 formed on the light emitting nanostructures 140 by depositing an insulating material at a second thickness equal to two times the first thickness.

In the case of the filling layer of FIG. 7A formed through a relatively thin deposition of the insulating material, upper portions of the refractive portions 162 may be exposed through the filling layer 160. In the case of the filling layer of FIG. 7B formed through a relatively thick deposition of the insulating material, the refractive portions 162 may be relatively long and thin, such that they are completely enclosed by the cover portion 164. Therefore, it may be appreciated that the size and position of the refractive portion 162 may be adjusted by the degree of deposition of the material forming the cover portion 164.

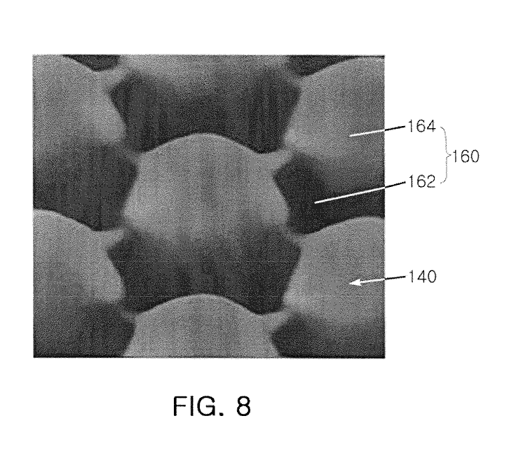

FIG. 8 illustrates the top surface of the filling layer 160 analyzed by the SEM.

FIG. 8 illustrates the cover portions 164 covering the light emitting nanostructures arranged in a hexagonal pattern and the refractive portions 162 having top portions thereof exposed. As described, the refractive portion 162 may be exposed by adjusting a filling rate of the cover portion 164, and the refractive portion 162 may be, for example, filled with a material having a high refractive index.

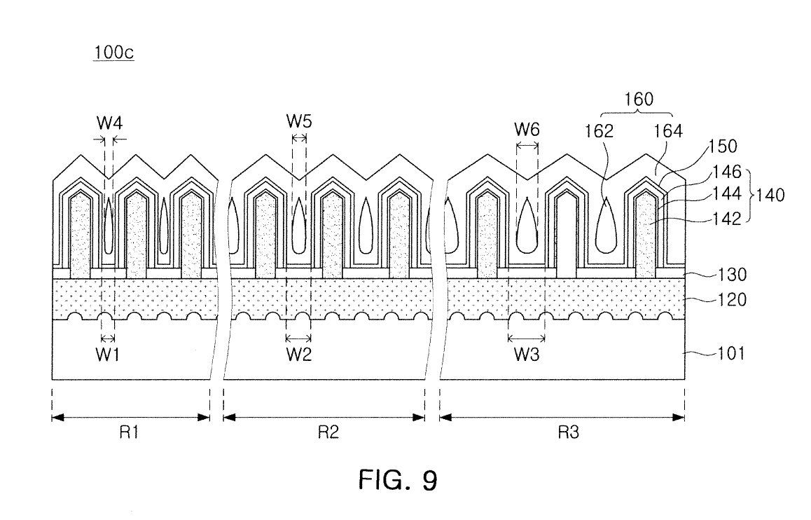

With reference to FIG. 9, a semiconductor light emitting device 100c may include the substrate 101, the first conductivity-type semiconductor base layer 120 formed on the substrate 101, the insulating layer 130, the light emitting nanostructure 140, the transparent electrode layer 150 and the filling layer 160. The light emitting nanostructure 140 may include the first conductivity-type semiconductor core 142 grown from the first conductivity-type semiconductor base layer 120, the active layer 144 and the second conductivity-type semiconductor layer 146. Some elements of the semiconductor light emitting device 100c such as the first and second electrodes 170 and 180 are not illustrated in FIG. 9.

The semiconductor light emitting device 100c according to the present embodiment may include first to third regions R1, R2 and R3, and a distance between the light emitting nanostructures 140 in respective regions may be differently set to be first to third distances W1, W2 and W3. The first distance W1 may be the shortest and the third distance W3 may be the longest. Accordingly, a width of the refractive portion 162 disposed between the light emitting nanostructures 140 in respective regions may be differently set to be fourth to sixth widths W4, W5 and W6. The fourth width W4 may be the narrowest and the sixth W6 may be the widest.

As in the present embodiment, in a case in which the semiconductor light emitting device 100c includes the first to third regions R1, R2 and R3 with different distances between the light emitting nanostructures 140, the active layers 144 within the light emitting nanostructures 140 grown in respective regions may have different contents of In or different growth thicknesses. For example, in a case in which they are grown under the same conditions, as a distance between the light emitting nanostructures 140 increases, the content of In within the active layer 144 may increase and the growth thickness thereof may increase. Therefore, the light emitting nanostructures 140 grown in the first to third regions R1, R2 and R3 may emit light having different wavelengths, and the emitted light may be combined to produce white light.

According to exemplary embodiments, the size of the light emitting nanostructures 140 may also be different in the first to third regions R1, R2 and R3.

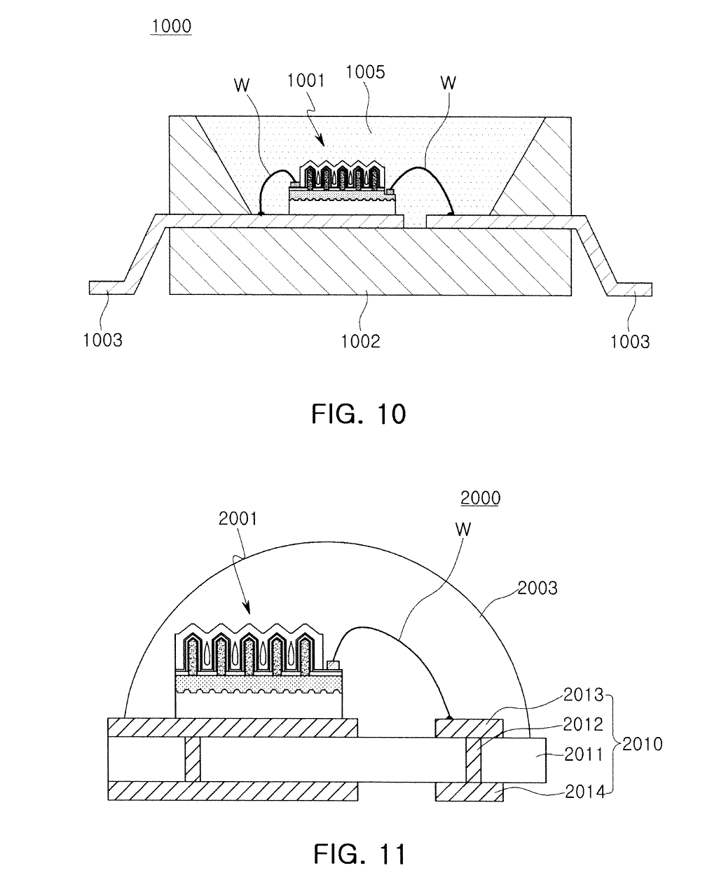

With reference to FIG. 10, a semiconductor light emitting device package 1000 may include a semiconductor light emitting device 1001, a package body 1002, and a pair of lead frames 1003. The semiconductor light emitting device 1001 may be mounted on the lead frames 1003 and electrically connected thereto using wires W. According to exemplary embodiments, the semiconductor light emitting device 1001 may be mounted on a portion of the package 1000 other than the lead frames 1003, for example, on the package body 1002. In addition, the package body 1002 may have a cup shape, such that light reflection efficiency may be improved. Such a reflective cup may contain a sealing body 1005 formed of a light transmissive material and sealing the semiconductor light emitting device 1001, the wires w and the like. In the present embodiment, the semiconductor light emitting device package 1000 includes the semiconductor light emitting device 1001 having the same structure as that of the semiconductor light emitting device 100 illustrated in FIG. 1 by way of example; however, the semiconductor light emitting device package 1000 may include any one of the semiconductor light emitting devices 100a, 100b and 100c illustrated in FIGS. 4, 5 and 9.

With reference to FIG. 11, a semiconductor light emitting device package 2000 may include a semiconductor light emitting device 2001, a mounting substrate 2010, and a sealing body 2003. The semiconductor light emitting device 2001 may be mounted on the mounting substrate 2010 and be electrically connected to the mounting substrate 2010 using the wire W and the substrate 101 (see FIG. 1). In the present embodiment, the substrate 101 may be a conductive substrate.

The mounting substrate 2010 may include a substrate body 2011, an upper electrode 2013 and a lower electrode 2014. In addition, the mounting substrate 2010 may include a through electrode 2012 connecting the upper electrode 2013 to the lower electrode 2014. The mounting substrate 2010 may be provided as a printed circuit board (PCB), a metal core printed circuit board (MCPCB), a metal printed circuit board (MPCB), a flexible printed circuit board (—PCB) or the like. The structure of the mounting substrate 2010 may be varied.

The sealing body 2003 may have a dome-like lens structure, the top of which is convex. According to exemplary embodiments, the sealing body 2003 may be formed to have a lens structure including convex or concave portions on a surface thereof, thereby adjusting an angle of light emitted through the top of the sealing body 2003.

In the present embodiment, the semiconductor light emitting device package 2000 includes the semiconductor light emitting device 2001 in which the first electrode 170 in the structure of the semiconductor light emitting device 100 illustrated in FIG. 1 is replaced with the substrate 101; however, the semiconductor light emitting device package 2000 may include any one of the semiconductor light emitting devices 100a, 100b and 100c illustrated in FIGS. FIGS. 4, 5 and 9 with the first electrode 170 replaced.

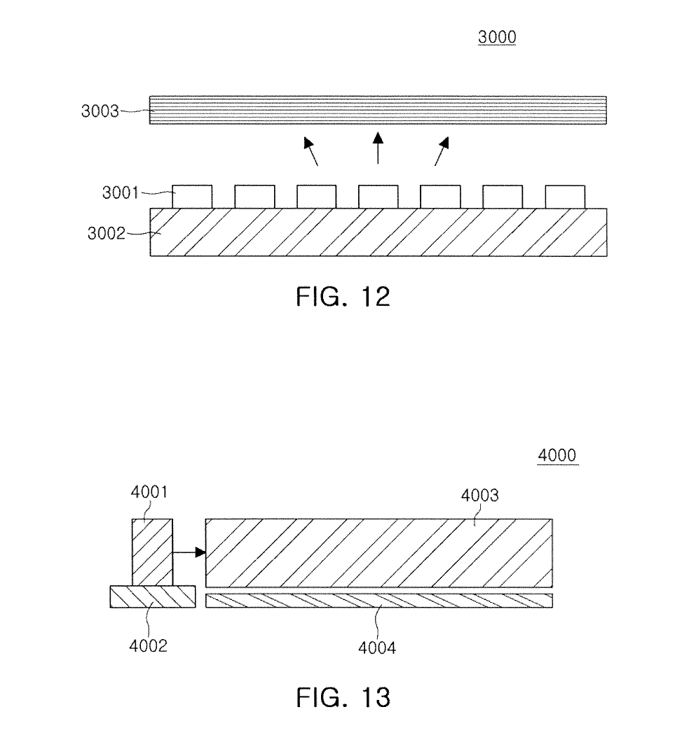

With reference to FIG. 12, a backlight unit 3000 may include at least one light source 3001 mounted on a substrate 3002 and at least one optical sheet 3003 disposed thereabove. The light source 3001 may be a semiconductor light emitting device package having the same structure as the above-described structures of FIGS. 10 and 11 or a structure similar thereto, or a chip-on-board (COB) type package in which a semiconductor light emitting device is directly mounted on the substrate 3002.

The light source 3001 in the backlight unit 3000 of FIG. 12 emits light toward a liquid crystal display (LCD) device disposed thereabove, whereas a light source 4001 mounted on a substrate 4002 in a backlight unit 4000 according to another embodiment illustrated in FIG. 13 emits light laterally and the light is incident to a light guide plate 4003 such that the backlight unit 4000 may serve as a surface light source. The light travelling to the light guide plate 4003 may be emitted upwardly and a reflective layer 4004 may be formed below a bottom surface of the light guide plate 4003 in order to improve light extraction efficiency.

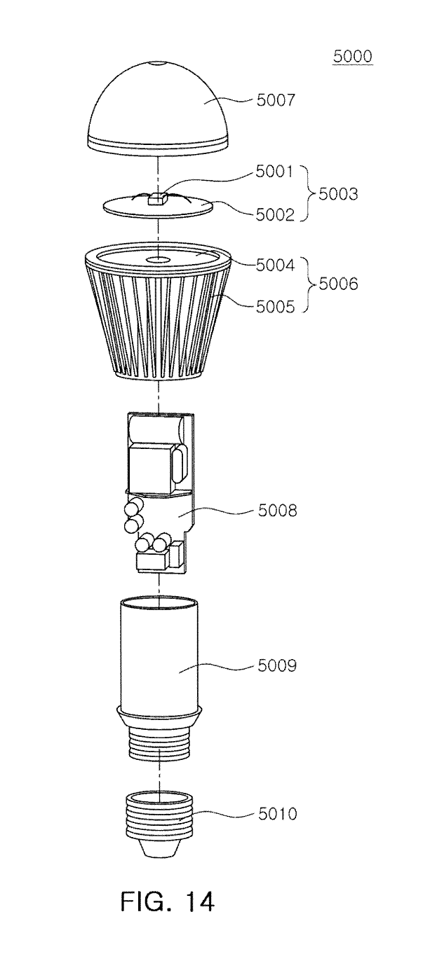

With reference to an exploded perspective view of FIG. 14, a lighting device 5000 is exemplified as a bulb-type lamp, and may include a light emitting module 5003, a driver 5008 and an external connector 5010. In addition, the lighting device 5000 may further include exterior structures, such as external and internal housings 5006 and 5009, a cover 5007, and the like. The light emitting module 5003 may include a semiconductor light emitting device 5001 having the same structure as that of the semiconductor light emitting device 100, 100a, 100b or 100c of FIGS. 1, 4, 5 and 9 or a structure similar thereto, and a circuit board 5002 having the semiconductor light emitting device 5001 mounted thereon. In the present embodiment, a single semiconductor light emitting device 5001 is mounted on the circuit board 5002 by way of example; however, a plurality of semiconductor light emitting devices may be mounted thereon as necessary. In addition, the semiconductor light emitting device 5001 may be mounted after being manufactured as a package, rather than being directly mounted on the circuit board 5002.

The external housing 5006 may serve as a heat radiator, and may include a heat sink plate 5004 in direct contact with the light emitting module 5003 to thereby improve heat dissipation, and heat radiating fins 5005 surrounding a side surface of the lighting device 5000. The cover 5007 may be disposed above the light emitting module 5003 and have a convex lens shape. The driver 5008 may be disposed inside the internal housing 5009 and be connected to the external connector 5010 such as a socket structure to receive power from an external power source. In addition, the driver 5008 may convert the received power into power appropriate for driving the semiconductor light emitting device 5001 of the light emitting module 5003 and supply the converted power thereto. For example, the driver 5008 may be provided as an AC-DC converter, a rectifying circuit part, or the like.

Although not shown, the lighting device 5000 may further include a communications module.

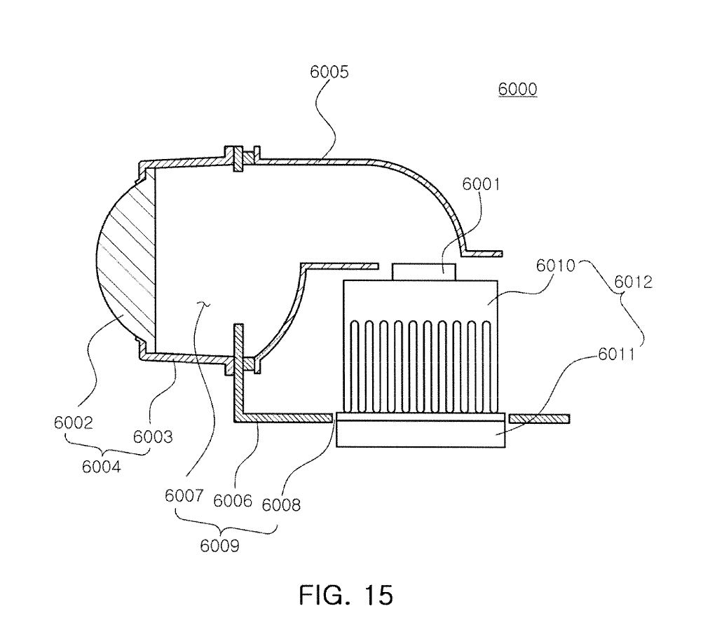

With reference to FIG. 15, a headlamp 6000 used in a vehicle or the like may include a light source 6001, a reflector 6005 and a lens cover 6004, and the lens cover 6004 may include a hollow guide part 6003 and a lens 6002. The light source 6001 may include at least one semiconductor light emitting device package of either FIG. 10 or 11. The headlamp 6000 may further include a heat radiator 6012 externally dissipating heat generated in the light source 6001. The heat radiator 6012 may include a heat sink 6010 and a cooling fan 6011 in order to effectively dissipate heat. In addition, the headlamp 6000 may further include a housing 6009 allowing the heat radiator 6012 and the reflector 6005 to be fixed thereto and supporting them. The housing 6009 may include a body 6006 and a central hole 6008 formed in one surface thereof, to which the heat radiator 6012 is coupled. In addition, the housing 6009 may include a forwardly open hole 6007 formed in the other surface thereof integrally connected to one surface thereof and bent in a direction perpendicular thereto. The reflector 6005 may be fixed to the housing 6009, such that light generated in the light source 6001 may be reflected by the reflector 6005, pass through the forwardly open hole 6007, and be emitted outwards.

As set forth above, according to exemplary embodiments of the present disclosure, a semiconductor light emitting device may have improved light extraction efficiency and reduced stress by disposing a filling layer including a refractive portion between light emitting nanostructures.

While exemplary embodiments have been shown and described above, it will be apparent to those skilled in the art that modifications and variations could be made without departing from the spirit and scope of the present disclosure as defined by the appended claims.

What is claimed is:

1. A semiconductor light emitting device, comprising:
a first conductivity-type semiconductor base layer;
a plurality of light emitting nanostructures disposed spaced apart from one another on the first conductivity-type semiconductor base layer, each light emitting nanostructure including a first conductivity-type semiconductor core, an active layer and a second conductivity-type semiconductor layer; and
a filling layer including a refractive portion disposed between the light emitting nanostructures and a cover portion filled between the light emitting nanostructures and enclosing the refractive portion.

2. The semiconductor light emitting device of claim 1, wherein the refractive portion is a void formed inside the cover portion.

3. The semiconductor light emitting device of claim 1, wherein the refractive portion includes a material having a refractive index different from a refractive index of the cover portion and the light emitting nanostructures.

4. The semiconductor light emitting device of claim 1, wherein the cover portion is disposed on the first conductivity-type semiconductor base layer between the light emitting nanostructures while covering at least a part of top and side surfaces of the light emitting nanostructures.

5. The semiconductor light emitting device of claim 1, wherein at least portions of the cover portion are continuously disposed above the light emitting nanostructures.

6. The semiconductor light emitting device of claim 1, wherein a top portion of the refractive portion is exposed through a top of the filling layer.

7. The semiconductor light emitting device of claim 1, wherein upper portions of the light emitting nanostructures protrude above a top of the filling layer.

8. The semiconductor light emitting device of claim 1, wherein the refractive portion comprises at least one refractive portion disposed between each pair of adjacent light emitting nanostructures.

9. The semiconductor light emitting device of claim 1, wherein the light emitting nanostructures have a hexagonal cross-section at a surface parallel to a top surface of the first conductivity-type semiconductor base layer, and
six of the light emitting nanostructures are arranged to surround a single light emitting nanostructure.

10. The semiconductor light emitting device of claim 9, wherein the refractive portion comprises six or more refractive portions disposed around the single light emitting nanostructure.

11. The semiconductor light emitting device of claim 9, wherein the light emitting nanostructure includes:
a first region having a hexagonal pyramid shape disposed in an upper portion thereof; and
a second region having a hexagonal column shape disposed below the first region.

12. The semiconductor light emitting device of claim 1, wherein the light emitting nanostructure further includes a transparent electrode layer disposed on the second conductivity-type semiconductor layer.

13. The semiconductor light emitting device of claim 12, wherein the transparent electrode layer is continuously disposed on adjacent light emitting nanostructures.

14. The semiconductor light emitting device of claim 1, further comprising first to third regions,
wherein the plurality of light emitting nanostructures have different distances in the first to third regions, and
the refractive portion has different sizes in proportion to the distances.

15. A semiconductor light emitting device comprising:
a first conductivity-type semiconductor base layer;
a plurality of light emitting nanostructures disposed spaced apart from one another on the first conductivity-type semiconductor base layer, each light emitting nanostructure including a first conductivity-type semiconductor core, an active layer and a second conductivity-type semiconductor layer; and
a filling layer filled between the light emitting nanostructures and having a void formed therein.

16. A semiconductor light emitting device, comprising:
a first conductivity-type semiconductor base layer;
a plurality of light emitting nanostructures disposed spaced apart from one another on the first conductivity-type semiconductor base layer, each light emitting nanostructure including a first conductivity-type semiconductor core, an active layer and a second conductivity-type semiconductor layer; and
a filling layer covering the plurality of light emitting nanostructures and filling the space between the light emitting nanostructures, the filling layer having voids between the light emitting nanostructures, wherein the filling layer has a higher top surface in the area below which the plurality of light emitting nanostructures are located than that of the area below which the voids are located.

17. The semiconductor light emitting device of claim 16, wherein the light emitting nanostructures have a hexagonal cross-section at a surface parallel to a top surface of the first conductivity-type semiconductor base layer, and
six of the light emitting nanostructures are arranged to surround a single light emitting nanostructure.

18. The semiconductor light emitting device of claim 16, wherein the light emitting nano structure includes:
a first region having a hexagonal pyramid shape disposed in an upper portion thereof; and
a second region having a hexagonal column shape disposed below the first region.

19. The semiconductor light emitting device of claim 16, wherein the light emitting nanostructure further includes a transparent electrode layer disposed on the second conductivity-type semiconductor layer.

20. The lighting device of claim 19, wherein the transparent electrode layer is continuously disposed on adjacent light emitting nanostructures.
